(19) United States
(12) Patent Application Publication
(10) Pub. No.: US 2017/0288013 A1
(43) Pub. Date: Oct. 5, 2017

(54) SEMICONDUCTOR DEVICE AND METHOD OF MANUFACTURING THE SAME

(71) Applicant: Renesas Electronics Corporation, Tokyo (JP)

(72) Inventor: Shigeo TOKUMITSU, Hitachinaka-shi (JP)

(73) Assignee: Renesas Electronics Corporation, Tokyo (JP)

(21) Appl. No.: 15/468,324

(22) Filed: Mar. 24, 2017

(30) Foreign Application Priority Data
Mar. 29, 2016 (JP) 2016-065870

(51) Int. Cl. H01L 29/04; H01L 23/528; H01L 29/10; H01L 21/8238; H01L 29/06; H01L 27/092

(52) U.S. Cl. CPC H01L 29/04; H01L 29/0642; H01L 27/0922; H01L 29/1095; H01L 21/823878; H01L 23/5283; H01L 21/823892; H01L 21/823871

(57) ABSTRACT

A semiconductor device includes a high voltage transistor formation region defined by an element isolation insulating film, a transistor formation region defined by an element isolation insulating film, and a substrate contact portion. A crystal defect region is formed at a portion of a semiconductor substrate that is positioned immediately below each of the substrate contact portion and element isolation insulating films.

This nonprovisional application is based on Japanese Patent Application No. 2016-065870 filed on Mar. 29, 2016 with the Japan Patent Office, the entire contents of which are hereby incorporated by reference.

### BACKGROUND OF THE INVENTION

### Field of the Invention

The present invention relates to a semiconductor device and a method of manufacturing the same and, for example, is suitably used for a semiconductor device including a substrate contact portion to a semiconductor substrate.

### Description of the Background Art

In semiconductor devices mounted on automobiles, a variety of semiconductor elements, for example, such as CMOS (Complementary Metal Oxide Semiconductor) transistors, high voltage NMOS transistors, high voltage PMOS transistors, and bipolar transistors are formed. These semiconductor elements are formed in an element formation region in a semiconductor substrate. The element formation region is defined by an element isolation insulating film formed in the semiconductor substrate.

Furthermore, in such a semiconductor device, a substrate contact portion is formed for fixing the semiconductor substrate to a predetermined potential. The substrate contact portion is disposed in a region outside the element formation region. An example of patent documents disclosing such a substrate contact portion is Patent Document 1 (Japanese Patent Laying-Open No. 2015-37099).

### SUMMARY OF THE INVENTION

In a process of manufacturing a semiconductor device, micro-defects (BMD: Bulk Micro Defect) are generated in the semiconductor substrate for gettering of metal contamination. In order to generate micro-defects, oxygen is introduced in advance in the semiconductor substrate. The introduced oxygen is precipitated as SiO₂ between lattices by thermal treatment.

As the oxygen concentration in the semiconductor substrate decreases, the lifetime of carriers (electrons or holes) produced in one semiconductor element becomes longer. The inventors of the present invention have found that the distance of diffusion in the semiconductor substrate thus increases, and the diffusing carriers affect the operation of another semiconductor element as leak current.

A semiconductor device according to an embodiment includes a semiconductor substrate, a first element formation region in which a first semiconductor element is formed, a second element formation region in which a second semiconductor element is formed, a substrate contact portion, and a crystal defect region. The first element formation region is defined by a first insulating isolation portion reaching from the main surface to a first depth. The second element formation region is disposed at a distance from the first element formation region and defined by a second insulating isolation portion reaching from the main surface to the first depth. The substrate contact portion is formed in a region of the semiconductor substrate that is positioned between the first element formation region and the second element formation region. The substrate contact portion includes a portion reaching from the main surface to a second depth. The crystal defect region includes a first crystal defect region formed at a portion of the semiconductor substrate that is positioned immediately below the substrate contact portion.

A method of manufacturing a semiconductor device according to another embodiment includes the following steps. A first isolation groove defining a first element formation region and a second isolation groove defining a second element formation region are formed to reach from a main surface of a semiconductor substrate to a first depth, and an opening is formed to reach from the main surface of the semiconductor substrate positioned between the first isolation groove and the second isolation groove to the first depth. An insulating film is formed so as to fill the first isolation groove, the second isolation groove, and the opening to form a first insulating isolation portion in the first isolation groove and form a second insulating isolation portion in the second isolation groove. Processing is successively performed on a portion of the insulating film buried in the opening and on the semiconductor substrate to form a contact opening passing through the insulating film to reach the first depth. A conductor is formed in the contact opening to form a substrate contact portion. An injection seed not concerned with a conductivity type is injected to form a crystal defect region in the semiconductor substrate. The step of forming the crystal defect region includes the step of forming a first crystal defect region at a portion of the semiconductor substrate that is positioned immediately below the substrate contact portion.

In the semiconductor device according to an embodiment, malfunction of semiconductor elements due to leak current can be suppressed.

The method of manufacturing a semiconductor device according to another embodiment can produce a semiconductor device in which malfunction of semiconductor elements due to leak current is suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial plan view of a semiconductor device according to a first embodiment.

FIG. 2 is a cross-sectional perspective view showing a structure of the semiconductor substrate taken along line II-II shown in FIG. 1 in the first embodiment.

FIG. 3 is a cross-sectional view of the semiconductor device taken along line II-II shown in FIG. 1 in the first embodiment.

FIG. 4 is a cross-sectional view showing a step in a method of manufacturing a semiconductor device in the first embodiment.

FIG. 5 is a cross-sectional view showing a step performed after the step shown in FIG. 4 in the first embodiment.

FIG. 6 is a cross-sectional view showing a step performed after the step shown in FIG. 5 in the first embodiment.

FIG. 7 is a cross-sectional view showing a step performed after the step shown in FIG. 6 in the first embodiment.

FIG. 8 is a cross-sectional view showing a step performed after the step shown in FIG. 7 in the first embodiment.

FIG. 9 is a cross-sectional view showing a step performed after the step shown in FIG. 8 in the first embodiment.

FIG. 10 is a cross-sectional view showing a step performed after the step shown in FIG. 9 in the first embodiment.

FIG. 11 is a cross-sectional view showing a step performed after the step shown in FIG. 10 in the first embodiment.

FIG. 12 is a cross-sectional view showing a step performed after the step shown in FIG. 11 in the first embodiment.

FIG. 13 is a cross-sectional view of a semiconductor device according to a comparative example.

FIG. 14 is a cross-sectional view for explaining the problem of the semiconductor device according to the comparative example.

FIG. 15 is a cross-sectional view for explaining the operation effects of the semiconductor device in the first embodiment.

FIG. 16 is a cross-sectional view of a semiconductor device according to a second embodiment.

FIG. 17 is a cross-sectional view showing a step in a method of manufacturing a semiconductor device in the second embodiment.

FIG. 18 is a cross-sectional view showing a step performed after the step shown in FIG. 17 in the second embodiment.

FIG. 19 is a cross-sectional view for explaining the operation effects of the semiconductor device in the second embodiment.

FIG. 20 is a cross-sectional view of a semiconductor device according to a third embodiment.

FIG. 21 is a cross-sectional view showing a step in a method of manufacturing a semiconductor device in the third embodiment.

FIG. 22 is a cross-sectional view showing a step performed after the step shown in FIG. 21 in the third embodiment.

FIG. 23 is a cross-sectional view for explaining the operation effects of the semiconductor device in the third embodiment.

FIG. 24 is a partial plan view of a semiconductor device according to a first example in a fourth embodiment.

FIG. 25 is a partial plan view of a semiconductor device according to a second example in the fourth embodiment.

FIG. 26 is a partial plan view of a semiconductor device according to a third example in the fourth embodiment.

FIG. 27 is a partial plan view of a semiconductor device according to a fourth example in the fourth embodiment.

FIG. 28 is a partial plan view of a semiconductor device according to a fifth example in the fourth embodiment.

FIG. 29 is a partial plan view of a semiconductor device according to a sixth example in the fourth embodiment.

### DESCRIPTION OF THE PREFERRED EMBODIMENTS

### First Embodiment

A semiconductor device including a substrate contact portion according to a first embodiment will be described.

As previously described, a variety of semiconductor elements, for example, such as CMOS transistors, high voltage NMOS transistors, high voltage PMOS transistors, and bipolar transistors are formed in a semiconductor device. Here, for convenience of explanation, a high voltage NMOS transistor and a CMOS transistor are described as semiconductor elements, by way of example.

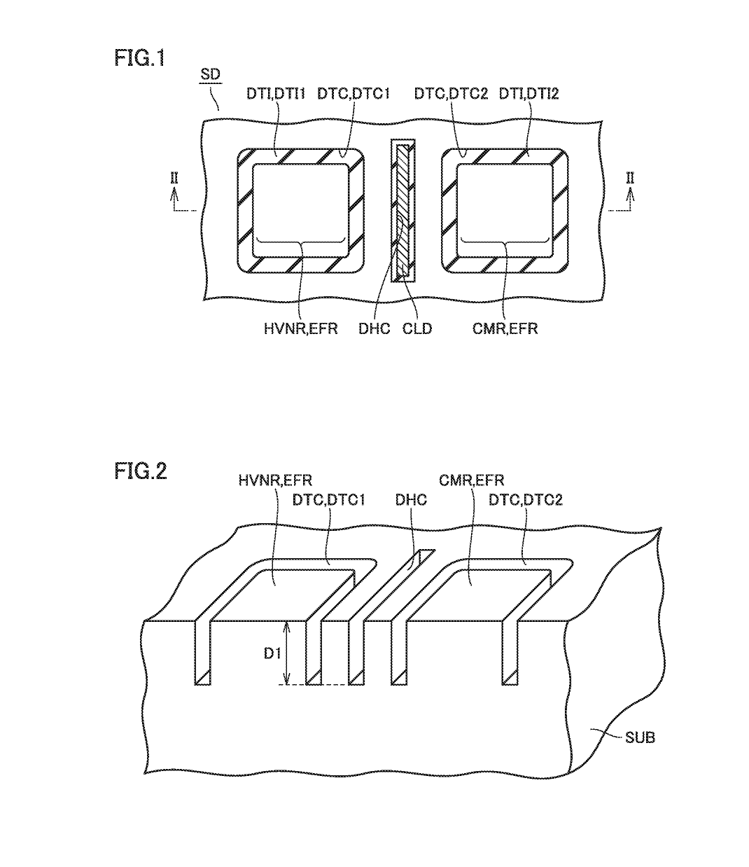

As shown in FIG. 1, in a semiconductor device SD, for example, a high voltage NMOS transistor formation region HVNR is defined as one of element formation regions EFR by an element isolation insulating film DTI1 (DTI). In addition, for example, a CMOS transistor formation region CMR is defined as another element formation region EFR by an element isolation insulating film DTI2 (DTI).

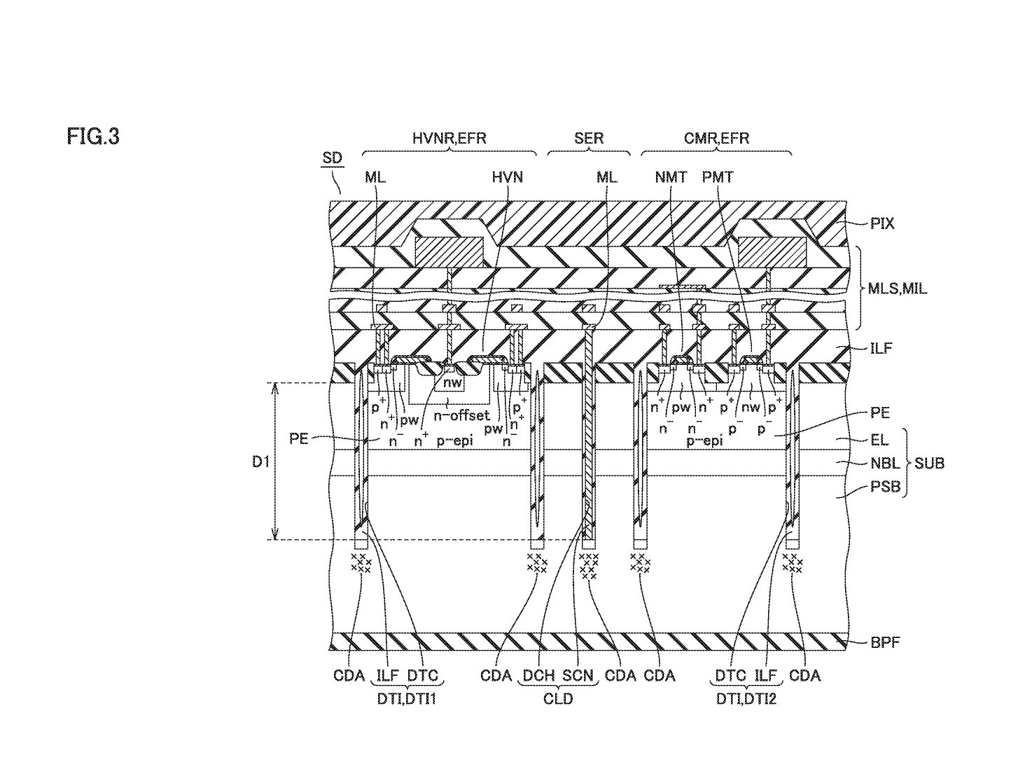

High voltage NMOS transistor formation region HVNR and CMOS transistor formation region CMR are disposed at a distance from each other. A substrate contact portion CLD is formed at a region (substrate electrode region SER) of semiconductor substrate SUB that is positioned between high voltage NMOS transistor formation region HVNR and CMOS transistor formation region CMR. Substrate contact portion CLD fixes semiconductor substrate SUB (p-type substrate PSB) to a predetermined potential (see FIG. 3).

Element isolation insulating film DTI1 (DTI) is formed in a trench DTC (DTC). Element isolation insulating film DTI2 (DTI) is formed in a trench DTC2 (DTC). Substrate contact portion CLD is formed in a contact groove DHC. As shown in FIG. 2, contact groove DHC is formed with the same depth (depth D1) as trenches DTC1, DTC2. It is noted that contact groove DHC may be formed deeper than depth D1 or shallower than depth D1.

The structure of semiconductor device SD will be described in more details. As shown in FIG. 3, semiconductor substrate SUB is formed with a p-type substrate PSB, an n-type buried region NBL, and an epitaxial layer EL. Element isolation insulating films DTI1, DTI2 are formed from the surface of semiconductor substrate SUB over depth D1. Element isolation insulating films DTI1, DTI2 pass through epitaxial layer EL and n-type buried region NBL to reach p-type substrate PSB.

A crystal defect region CDA is formed at a portion of p-type substrate PSB (semiconductor substrate SUB) that is positioned immediately below element isolation insulating film DTI1. A crystal defect region CDA is formed at a portion of p-type substrate PSB (semiconductor substrate SUB) that is positioned immediately below element isolation insulating film DTI2.

Substrate contact portion CLD is formed from the surface of semiconductor substrate SUB over depth D1. Substrate contact portion CLD passes through epitaxial layer EL and n-type buried region NBL to reach p-type substrate PSB. A crystal defect region CDA is formed at a portion of p-type substrate PSB (semiconductor substrate SUB) that is positioned immediately below substrate contact portion CLD. Substrate contact portion CLD may be formed deeper than depth D1 or may be formed shallower than depth D1.

In high voltage NMOS transistor formation region HVNR, p-type epitaxial layer PE is formed in epitaxial layer EL. A high voltage MOS transistor HVN is formed in p-type epitaxial layer PE. In CMOS transistor formation region CMR, p-type epitaxial layer PE is formed. An NMOS transistor NMT and a PMOS transistor PMT are formed in p-type epitaxial layer PE.

Insulating film TIT is formed so as to cover high voltage MOS transistor HVN, NMOS transistor NMT, PMOS transistor PMT, and the like. A plurality of first interconnection layers ML are formed on the surface of insulating film ILF. Of a plurality of first interconnection layers ML, a predetermined first interconnection layer ML is electrically connected to conductor portion SCN of substrate contact portion CLD.

On a plurality of first interconnection layers ML, multi-level interconnection layers MLS and multi-level interlayer insulating films MIL for insulating multi-level interconnection layers MLS from each other are formed. A polyimide film PIX is formed so as to cover multilayer interlayer insulating film MIL. Semiconductor device SD according to the first embodiment is configured as described above.

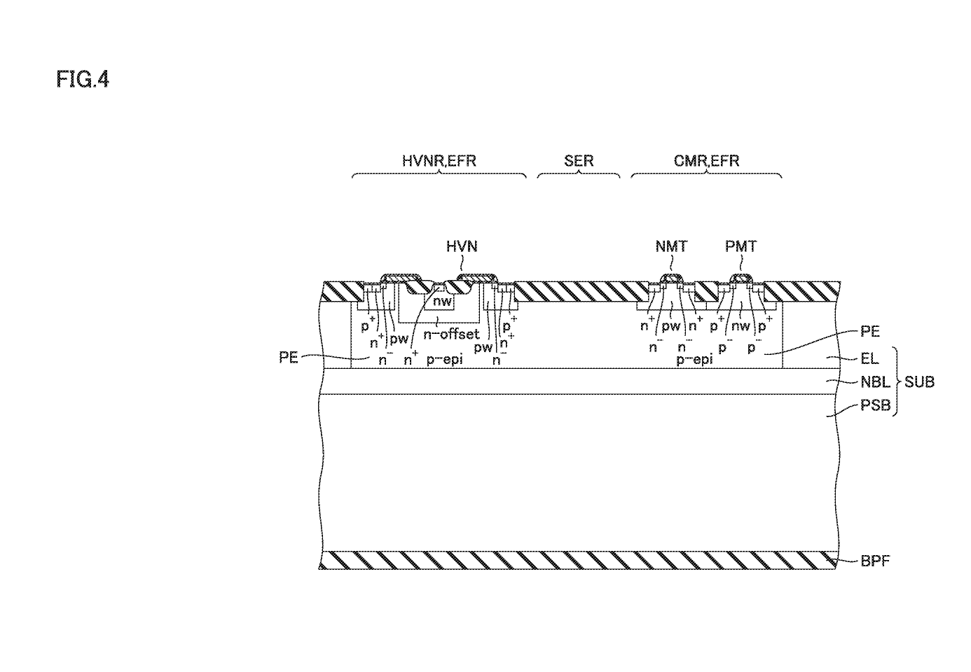

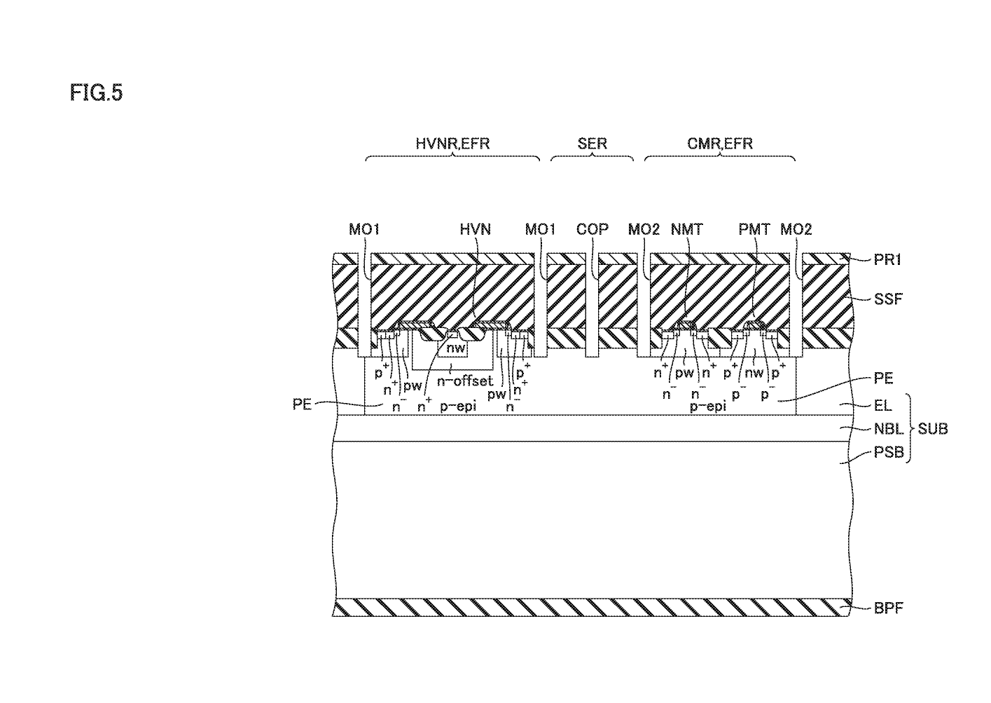

An example of a method of manufacturing the semiconductor device described above will now be described. First, as shown in FIG. 4, high voltage NMOS transistor HVN is formed in high voltage NMOS transistor formation region HVNR in semiconductor substrate SUB, and NMOS transistor NMT and PMOS transistor PMT are formed in CMOS transistor formation region CMR.

Next, for example, a silicon oxide film (not shown) serving as an etching mask is formed so as to cover high voltage NMOS transistor HVN, NMOS transistor NMT, PMOS transistor PMT, and the like. Next, a resist pattern PR1 (see FIG. 5) for forming a trench is formed by performing a predetermined photolithography process.

Next, as shown in FIG. 5, using resist pattern PR1 as an etching mask, a silicon oxide film SSF is etched to form an opening MO1 reaching p-type epitaxial layer PE in high voltage NMOS transistor formation region HVNR. An opening MO2 reaching p-type epitaxial layer PE is formed in CMOS transistor formation region CMR. In substrate electrode region SER positioned between high voltage NMOS transistor formation region HVNR and CMOS transistor formation region CMR, an opening COP reaching p-type epitaxial layer PE is formed.

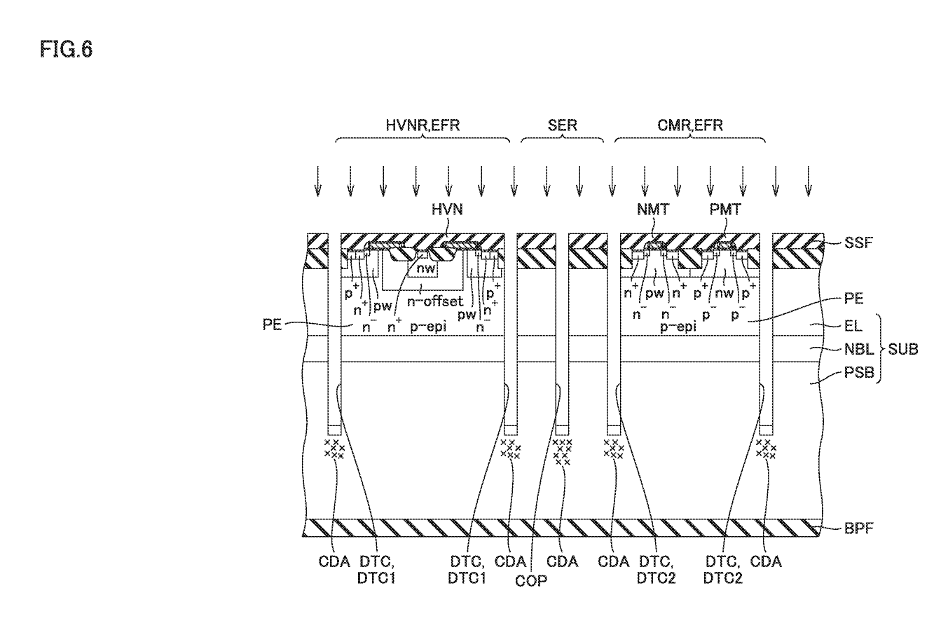

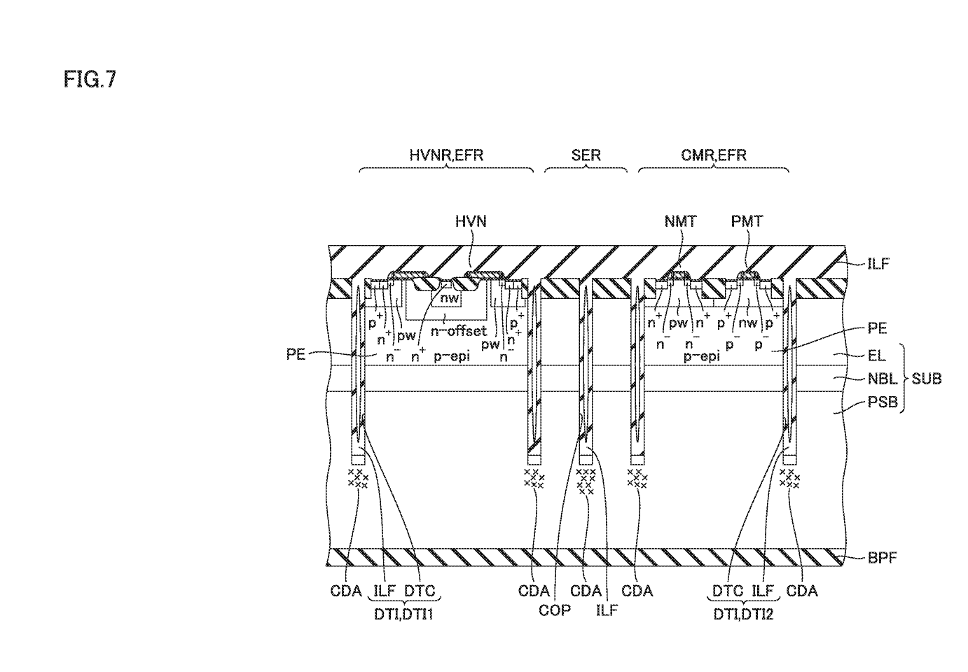

Next, as shown in FIG. 6, using silicon oxide film SSF and the like as an etching mask, the exposed p-type epitaxial layer PE is further etched to form a trench DTC1 reaching p-type substrate PSB in high voltage NMOS transistor formation region HVNR. A trench DTC2 reaching p-type substrate PSB is formed in CMOS transistor formation region CMR. An opening COP reaching p-type substrate PSB is formed in substrate electrode region SER.

Next, using silicon oxide film SSF and the like as an injection mask, an impurity not concerned with a conductivity type is injected to form crystal detect region CDA at a portion of p-type substrate PSB (semiconductor substrate SUB) that is positioned immediately below each of trenches DTC1, DTC2 and opening COP. Examples of the impurity not concerned with a conductivity type include carbon, silicon, germanium, and argon.

Next, a liner film (not shown), for example, formed of a silicon nitride film is formed so as to cover high voltage NMOS transistor HVN, NMOS transistor NMT, PMOS transistor PMT, and the like. Next, as shown in FIG. 7, an insulating film ILF, for example, such as a silicon oxide film is formed so as to cover high voltage NMOS transistor HVN, NMOS transistor NMT, PMOS transistor PMT, and the like.

Here, in high voltage NMOS transistor formation region HVNR, insulating film ILF is formed so as to cover the side surfaces and the bottom surface of trench TRC1. In CMOS transistor formation region CMR, insulating film ILF is formed so as to cover the side surfaces and the bottom surface of trench TRC2. In substrate electrode region SER, insulating film ILF is formed so as to cover the side surfaces and the bottom surface of opening COP.

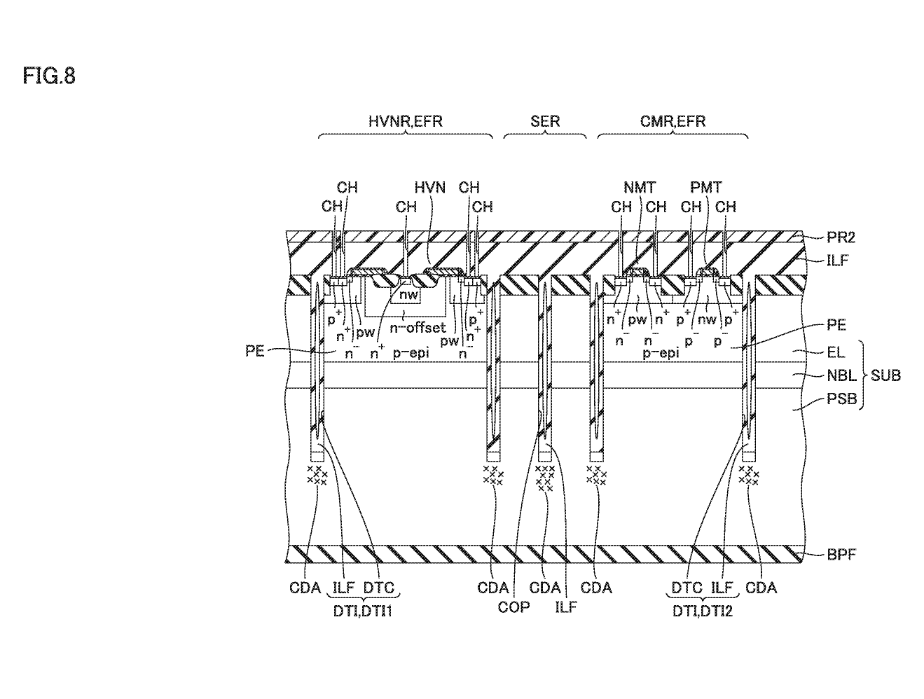

Next, as shown in FIG. 8, a predetermined photolithography process is performed to form a resist pattern PR2. Next, using resist pattern. PR2 as an etching mask, insulating film ILF is etched to form contact holes CH in each of high voltage NMOS transistor formation region HVNR and CMOS transistor formation region CMR. It is noted that the liner film (not shown) is exposed at the bottom of contact hole CH. Thereafter, resist pattern PR2 is removed.

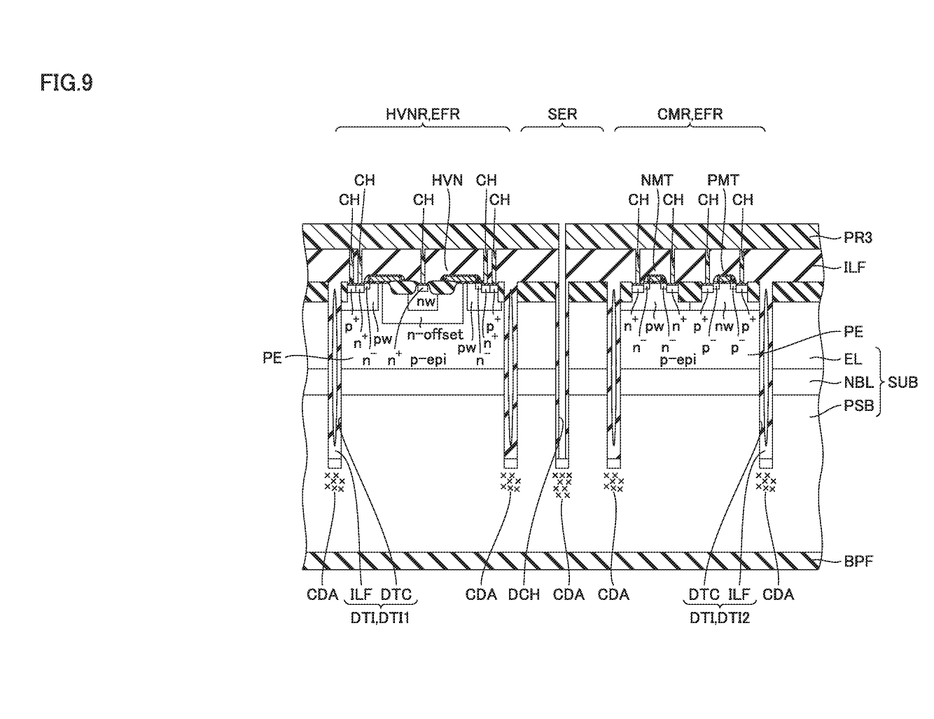

Next, as shown in FIG. 9, a predetermined photolithography process is performed to form a resist pattern PR3. Next, using resist pattern PR3 as an etching mask, insulating film ILF is etched to form contact groove DCH exposing p-type substrate PSB (semiconductor substrate SUB). Thereafter, resist pattern PR3 is removed.

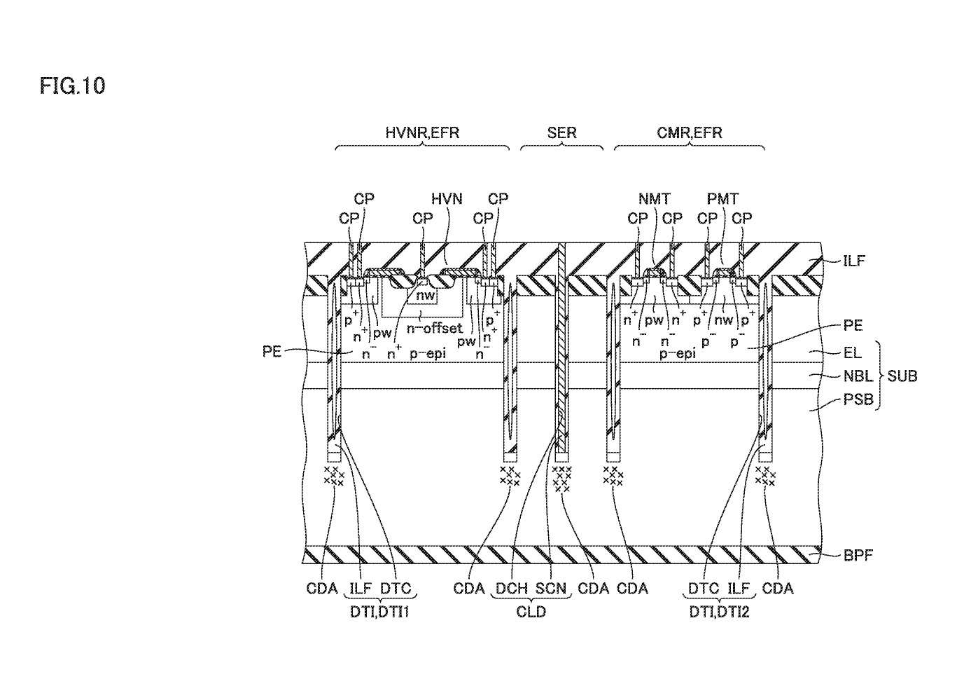

Next, the liner film exposed at the bottom of contact hole CH is removed. Next, a barrier metal film (not shown) and a metal film such as a tungsten film (not shown) are formed. Next, the metal film and the like are etched back or undergo chemical mechanical polishing. This process forms contact plugs CP in each of high voltage NMOS transistor formation region HVNR and CMOS transistor formation region CMR, as shown in FIG. 10. In substrate electrode region SER, a conductor portion SCN is formed.

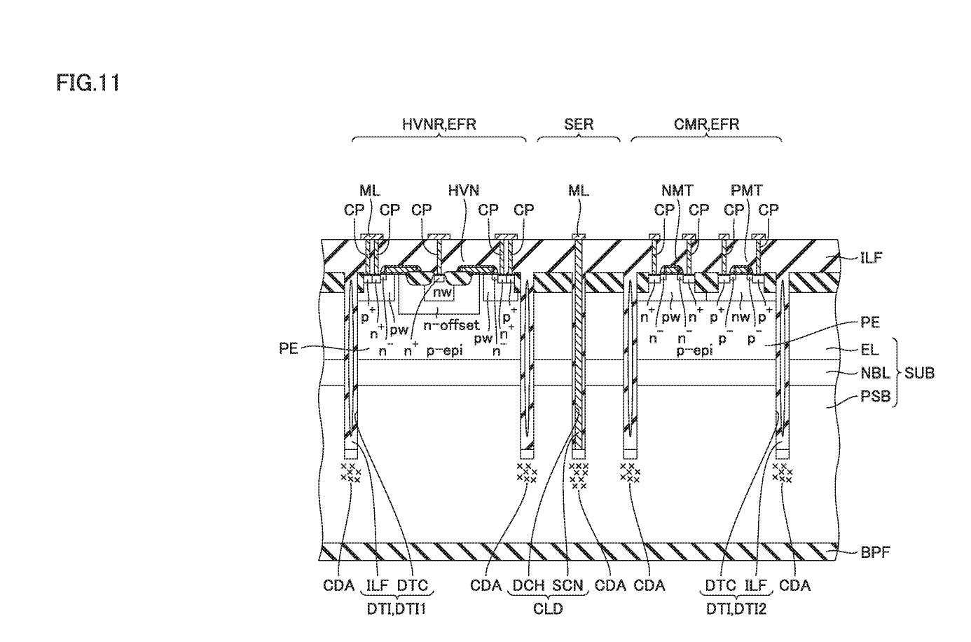

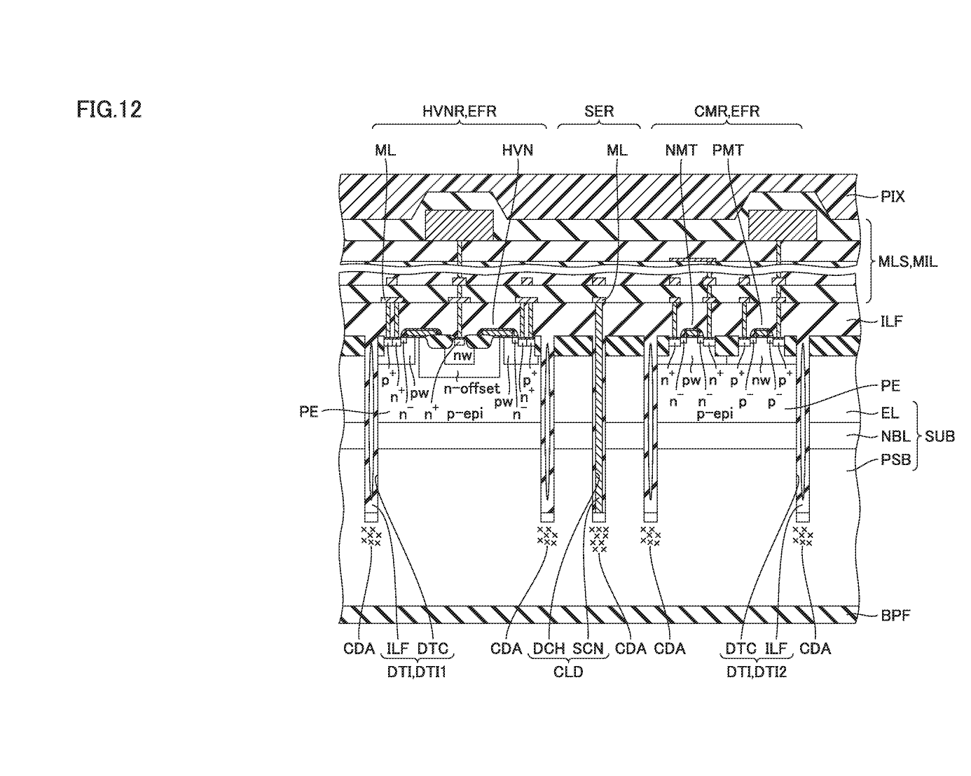

Next, as shown in FIG. 11, a plurality of first interconnection layers ML are formed on the surface of insulating film ILF. First interconnection layer ML may be an aluminum interconnection layer or copper wiring. Next, as shown in FIG. 12, the overlying multi-level interconnection layer MLS and multi-level interlayer insulating film MIL are formed as necessary. Thereafter, a polyimide film PIX is formed so as to cover multi-level interlayer insulating film MIL and the like. The main part of the semiconductor device is thus completed.

In the semiconductor device described above, crystal defect region CDA is formed at a portion of p-type substrate PSB (semiconductor substrate SUB) that is positioned immediately below each of element isolation insulating film DTI1, element isolation insulating film DTI2, and substrate contact portion CLD. This configuration can suppress the effect of carriers generated from a semiconductor element formed in one element formation region EFR on the operation of a semiconductor element formed in another element formation region EFR. This will be described in comparison with a semiconductor device according to a comparative example.

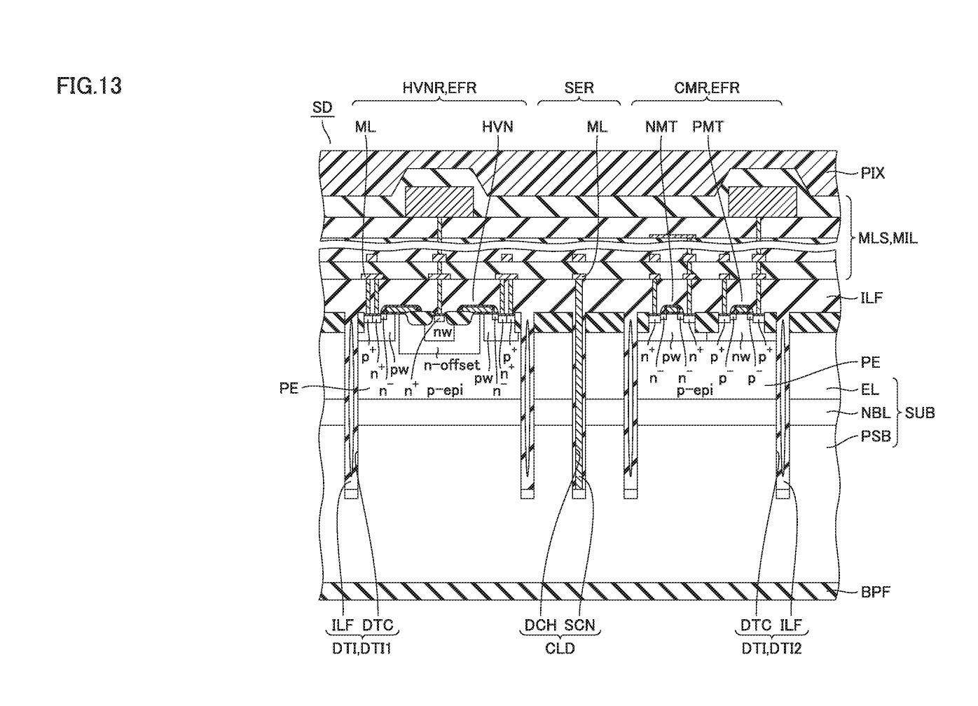

As shown in FIG. 13, a semiconductor device SD according to a comparative example is similar to the configuration of the semiconductor device shown in FIG. 3 except that crystal detect region CDA is not formed. Therefore, the same members are denoted with the same reference signs and a description thereof is not repeated unless necessary.

In general, in a semiconductor device, generation and annihilation of carriers (leak current) are repeated in connection with the operation of semiconductor elements. The generated carriers are annihilated at micro-defects (BMD) produced in the semiconductor substrate as the recombination center. The micro-defects depend on the concentration of oxygen introduced to semiconductor substrate SUB (p-type substrate PSB). As the oxygen concentration decreases, the micro-defects decrease. As micro-defects decrease, the recombination center of carriers decreases.

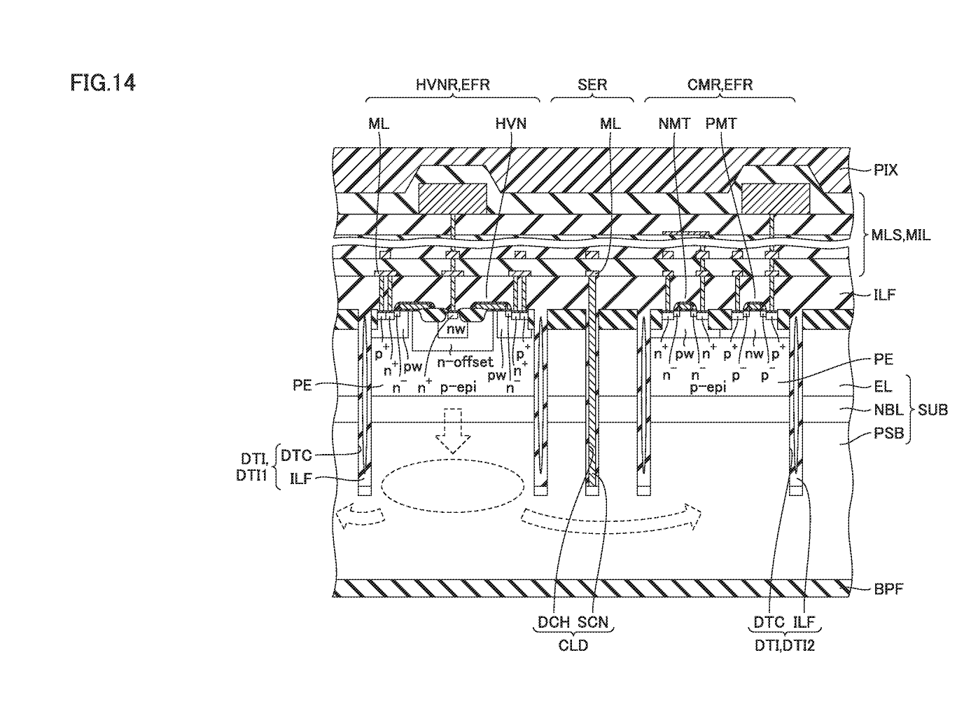

Here, it is supposed that carriers (electrons) are generated in connection with the operation of high voltage NMOS transistor NMT in semiconductor device SD according to the comparative example. As shown in FIG. 14, carriers (electrons) generated from high voltage NMOS transistor NMT are injected into p-type substrate PSB (see the dotted arrow). The carriers injected into p-type substrate PSB diffuse in p-type substrate PSB as substrate leak current. The carriers diffusing in p-type substrate PSB are, for example, recombined and annihilated in the micro-defects produced in p-type substrate PSB and thereby are reduced.

At this time, if the number of micro-defects in p-type substrate PSB decreases, the proportion of annihilated carriers decreases, and the lifetime of carriers becomes long. If the lifetime of carriers becomes long, the carriers may further diffuse in p-type substrate PSB to reach, for example, the region of p-type substrate PSB positioned at the adjacent CMOS transistor formation region CMR (see the dotted arrow). The inventors of the present invention have observed that the carders reaching the adjacent region may cause malfunction of NMOS transistor NMT or PMOS transistor PMT.

By contrast to semiconductor device SD according to the comparative example, semiconductor device SD according to the embodiment has crystal defect region CDA at a portion of p-type substrate PSB (semiconductor substrate SUB) that is positioned immediately below each of element isolation insulating film DTI1, element isolation insulating film DTI2, and substrate contact portion CLD.

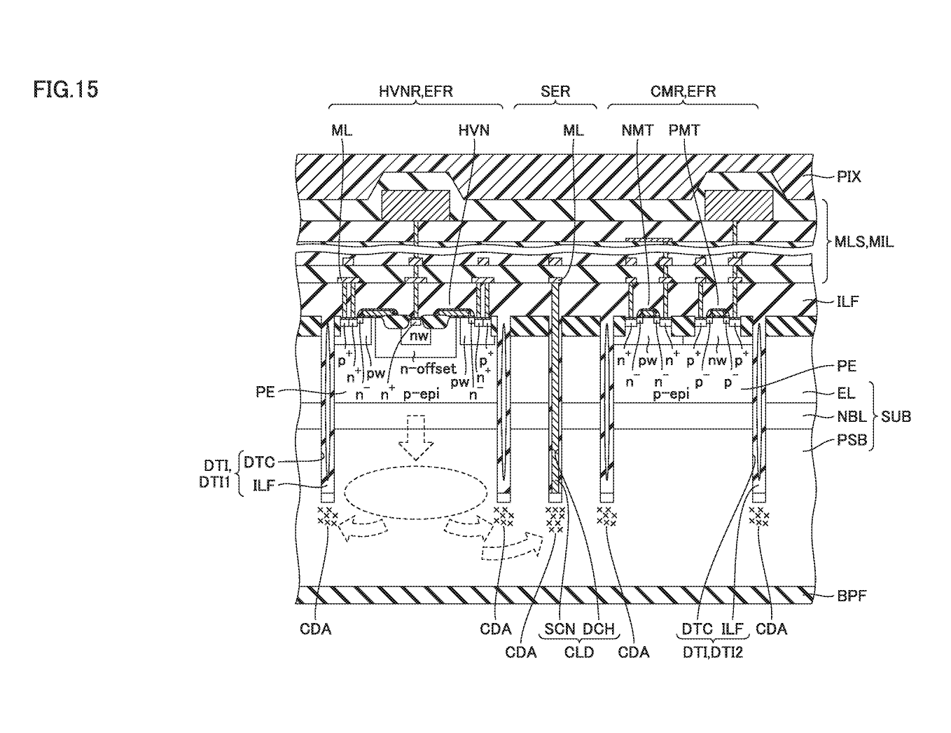

In this configuration, as shown in FIG. 15, the carriers diffusing toward CMOS transistor formation region CMR through p-type substrate PSB are recombined and annihilated in crystal defect region CDA. This can significantly reduce carriers diffusing toward CMOS transistor formation region CMR and can suppress malfunction of NMOS transistor NMT or PMOS transistor PMT.

### Second Embodiment

A semiconductor device including a substrate contact portion according to a second embodiment will be described.

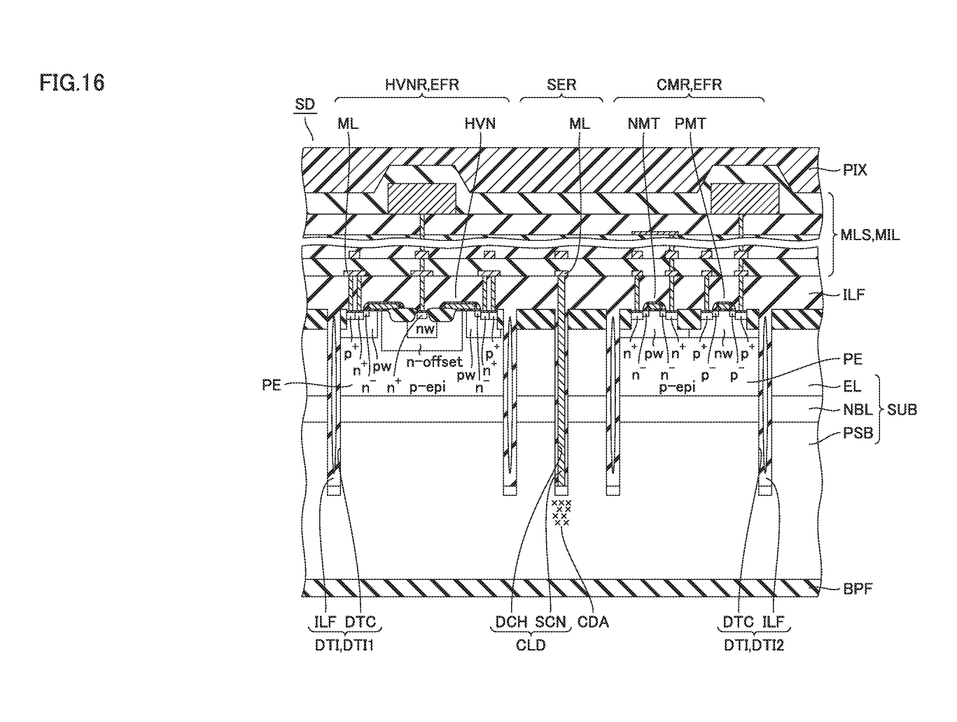

As shown in FIG. 16, in semiconductor device SD, crystal defect region CDA is formed at a portion of p-type substrate PSB (semiconductor substrate SUB) that is positioned immediately below substrate contact portion CLD. On the other hand, a crystal defect region is not formed at a portion of p-type substrate PSB (semiconductor substrate SUB) that is positioned immediately below each of element isolation insulating film DTI1 and element isolation insulating film DTI2. Except for this, the configuration is similar to the semiconductor device shown in FIG. 3, and the same members are denoted with the same reference signs and will not be further elaborated unless necessary.

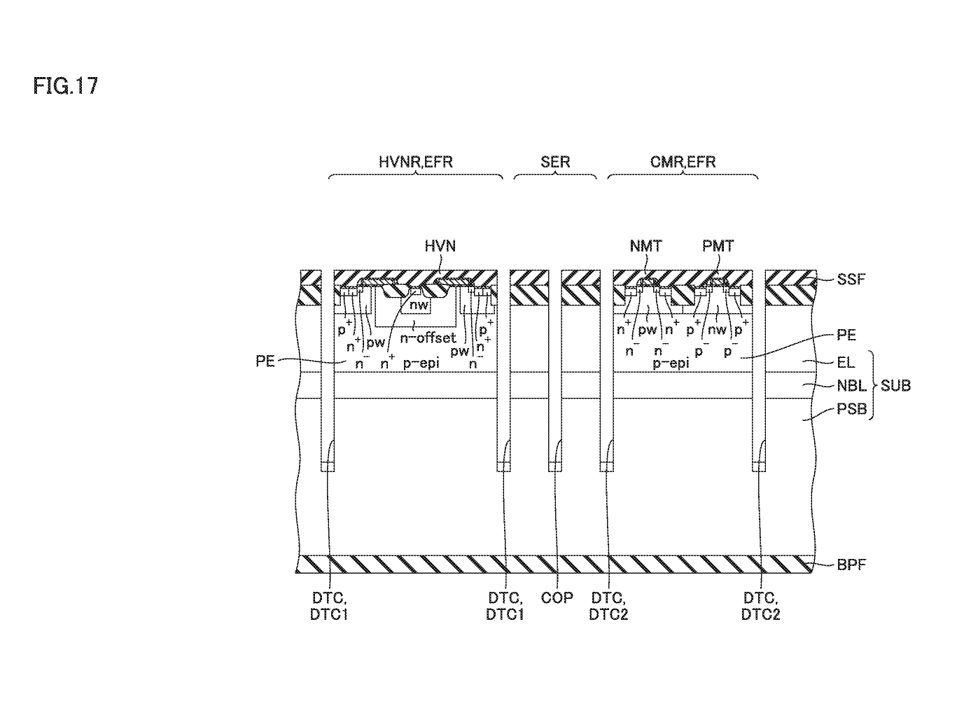

An example of a method of manufacturing the semiconductor device described above will be described. First, after the steps similar to the steps shown in FIG. 4 to FIG. 5, as shown in FIG. 17, using silicon oxide film SSF and the like as an etching mask, the exposed p-type epitaxial layer PE is further etched to form trench DTC1 reaching p-type substrate PSB in high voltage NMOS transistor formation region HVNR. In CMOS transistor formation region CMR, trench DTC2 reaching p-type substrate PSB is formed. In substrate electrode region SER, opening COP reaching p-type substrate PSB is formed. Here, impurity not concerned with a conductivity type is not injected.

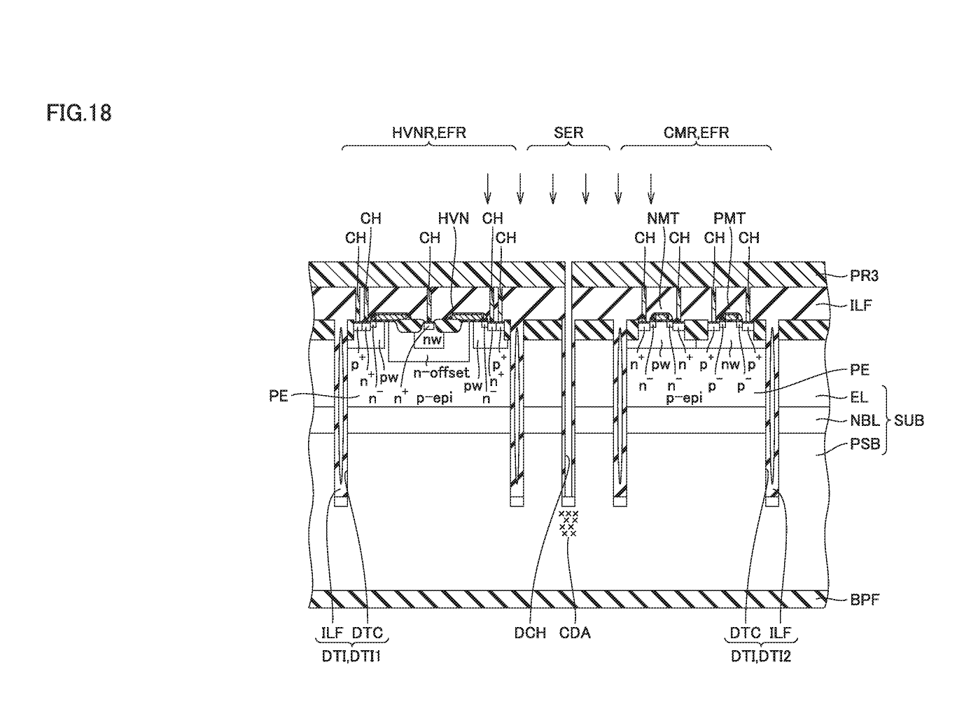

Next, through the steps similar to the steps shown in FIG. 7 to FIG. 9, as shown in FIG. 18, contact groove DCH is formed to expose p-type substrate PSB (semiconductor substrate SUB). Next, using resist pattern PR3 and insulating film ILF as an injection mask, an impurity not concerned with a conductivity type is injected to form crystal defect region CDA at a portion of p-type substrate PSB (semiconductor substrate SUB) that is positioned immediately below the bottom of contact groove DCH. Thereafter, resist pattern PR3 is removed. Next, through the steps similar to the steps shown in FIG. 10 to FIG. 12, the main part of the semiconductor device shown in FIG. 16 is completed.

In the aforementioned semiconductor device, crystal defect region CDA is formed at a portion of p-type substrate PSB (semiconductor substrate SUB) that is positioned immediately below substrate contact portion CLD disposed between high voltage NMOS transistor formation region HVNR and CMOS transistor formation region CMR.

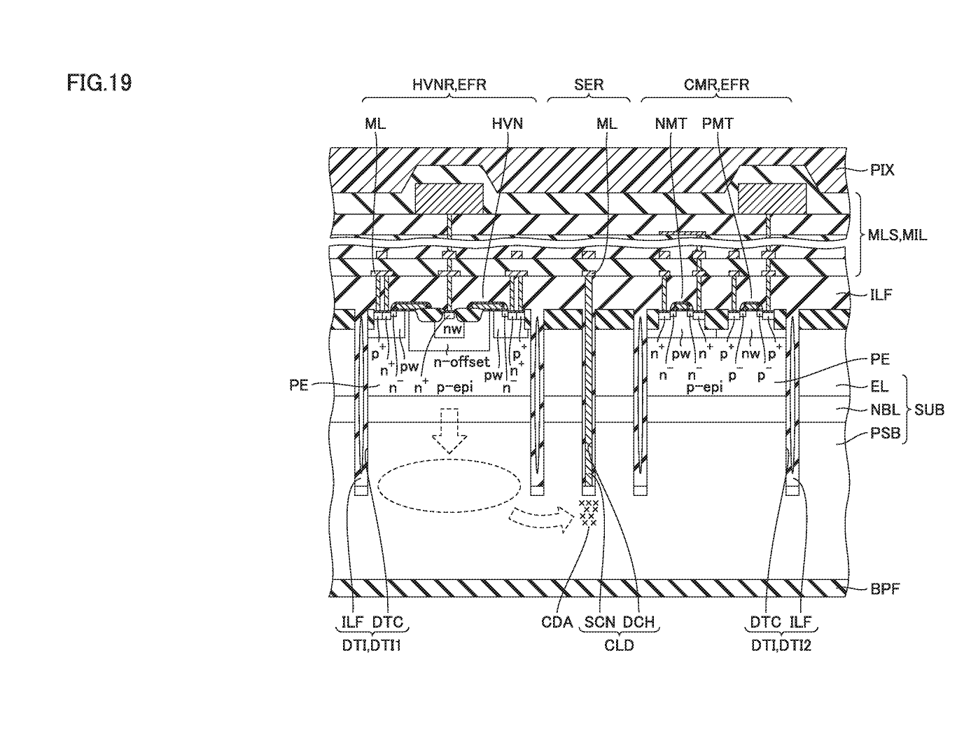

With this configuration, as shown in FIG. 19, the carriers diffusing toward CMOS transistor formation region CMR through p-type substrate PSB are recombined and annihilated in crystal defect region CDA. Thus, compared with the semiconductor device (see FIG. 13) according to the comparative example, the carriers diffusing toward CMOS transistor formation region CMR are significantly reduced, thereby suppressing malfunction of NMOS transistor NMT or PMOS transistor PMT.

### Third Embodiment

A semiconductor device including a substrate contact portion according to a third embodiment will be described.

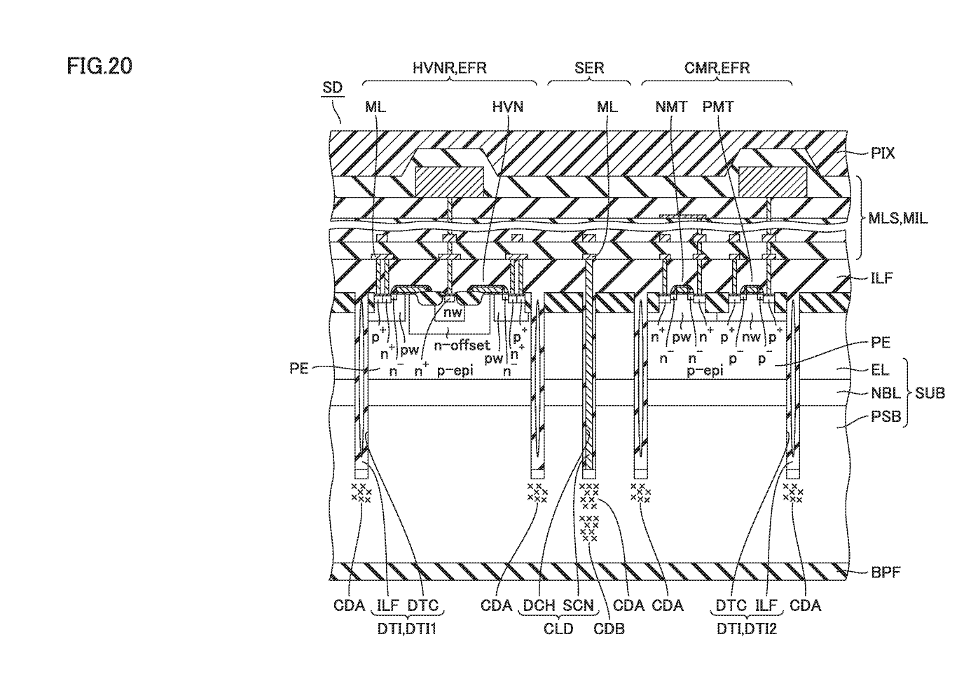

As shown in FIG. 20, in semiconductor device SD, crystal defect region CDA is formed at a portion of p-type substrate PSB (semiconductor substrate SUB) that is positioned immediately below each of element isolation insulating film DTI1 and element isolation insulating film DTI2. Crystal defect region CDA is also formed at a portion of p-type substrate PSB (semiconductor substrate SUB) that is positioned immediately below substrate contact portion CLD.

In addition, a crystal defect region CDB is formed at a portion of p-type substrate PSB (semiconductor substrate SUB) that is positioned immediately below crystal defect region CDA. Except for this, the configuration is similar to the semiconductor device shown in FIG. 3, and the same members are denoted with the same reference signs and will not be further elaborated unless necessary.

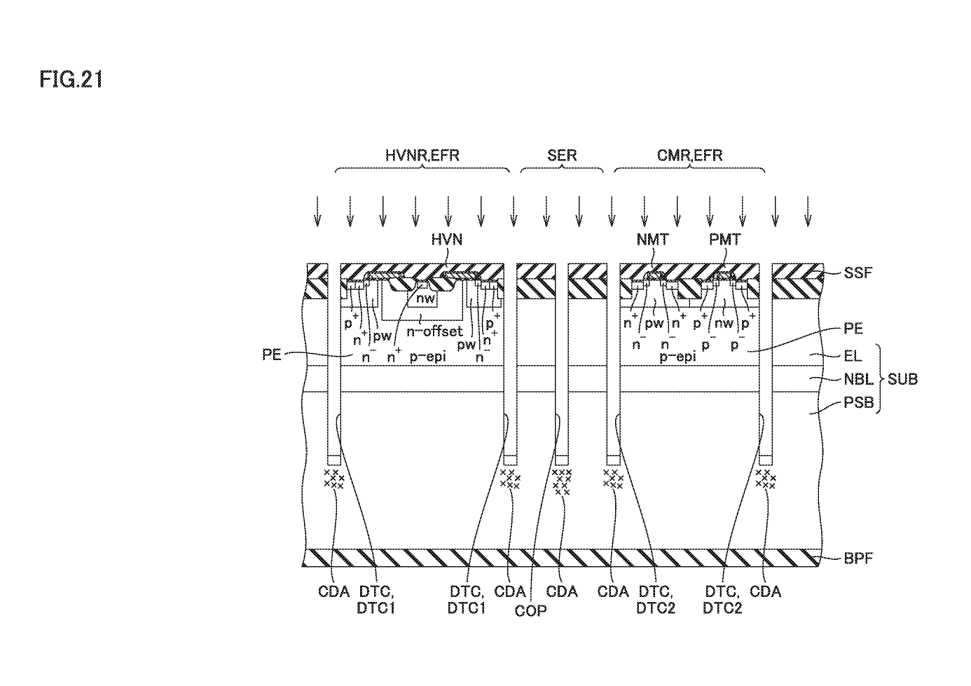

An example of a method of manufacturing the semiconductor device described above will now be described. First, after the steps similar to the steps shown in FIG. 4 to FIG. 5, as shown in FIG. 21, using silicon oxide film SSF and the like as an etching mask, the exposed p-type epitaxial layer PE is further etched to form trench DTC1 reaching p-type substrate PSB in high voltage NMOS transistor formation region HVNR. In CMOS transistor formation region CMR, trench DTC2 reaching p-type substrate PSB is formed. In substrate electrode region SER, opening COP reaching p-type substrate PSB is formed.

Next, using silicon oxide film SSF and the like as an injection mask, an impurity not concerned with a conductivity type is injected to form crystal defect region CDA at a portion of p-type substrate PSB (semiconductor substrate SUB) that is positioned immediately below the bottom of each of trench DTC1 and trench DTC2. Crystal defect region CDA is also formed at a portion of p-type substrate PSB (semiconductor substrate SUB) that is positioned immediately below the bottom of opening COP.

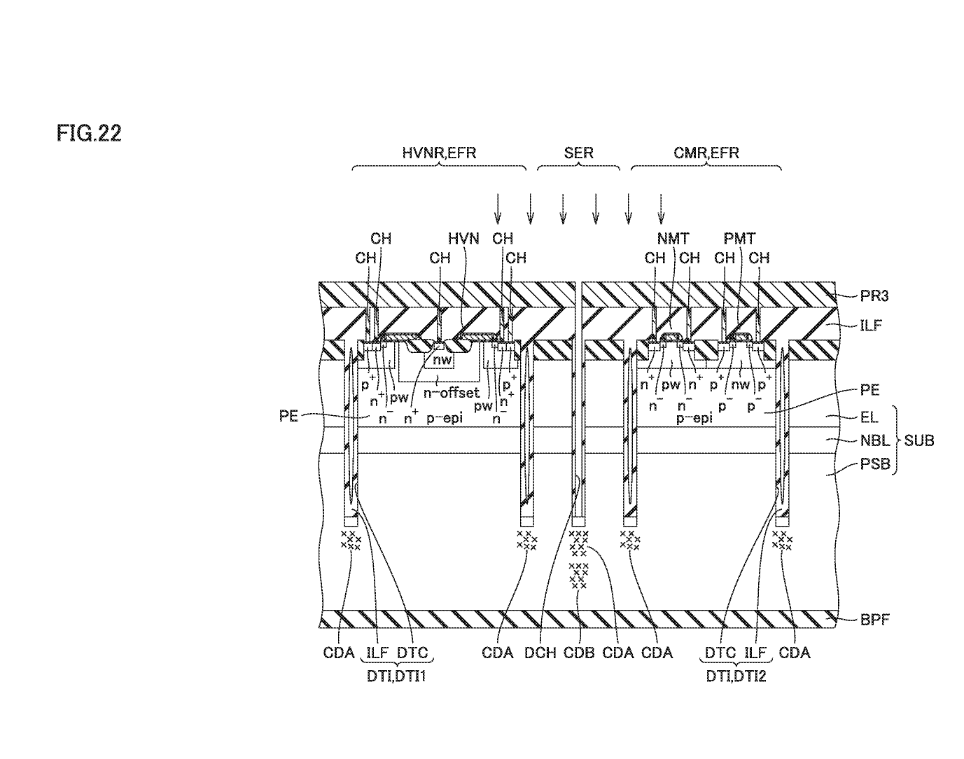

Next, through the steps similar to the steps shown in FIG. 7 to FIG. 9, as shown in FIG. 22, contact groove DCH is formed to expose p-type substrate PSB (semiconductor substrate SUB). Next, using resist pattern PR3 and insulating film ILF as an injection mask, an impurity not concerned with a conductivity type is injected to form crystal defect region CDB at a portion of p-type substrate PSB (semiconductor substrate SUB) that is positioned immediately below the bottom of contact groove DCH.

Here, since resist pattern PR3 and insulating film ILF are used as an injection mask, the injection mask is a relatively thick injection mask. Therefore, an impurity can be injected with injection energy higher than the injection energy for forming crystal defect region CDA. Thus, crystal defect region CDB is formed at a position deeper than crystal defect region CDA. Thereafter, resist pattern PR3 is removed. Next, through the steps similar to the steps shown in FIG. 10 to FIG. 12, the main part of the semiconductor device shown in FIG. 16 is completed.

In the aforementioned semiconductor device, crystal defect region CDA is formed at a portion of p-type substrate PSB (semiconductor substrate SUB) that is positioned immediately below each of element isolation insulating film DTI1, element isolation insulating film DTI2, and substrate contact portion CLD. In addition, crystal defect region CDB is formed at a position deeper than crystal defect region CDA, immediately below substrate contact portion CLD.

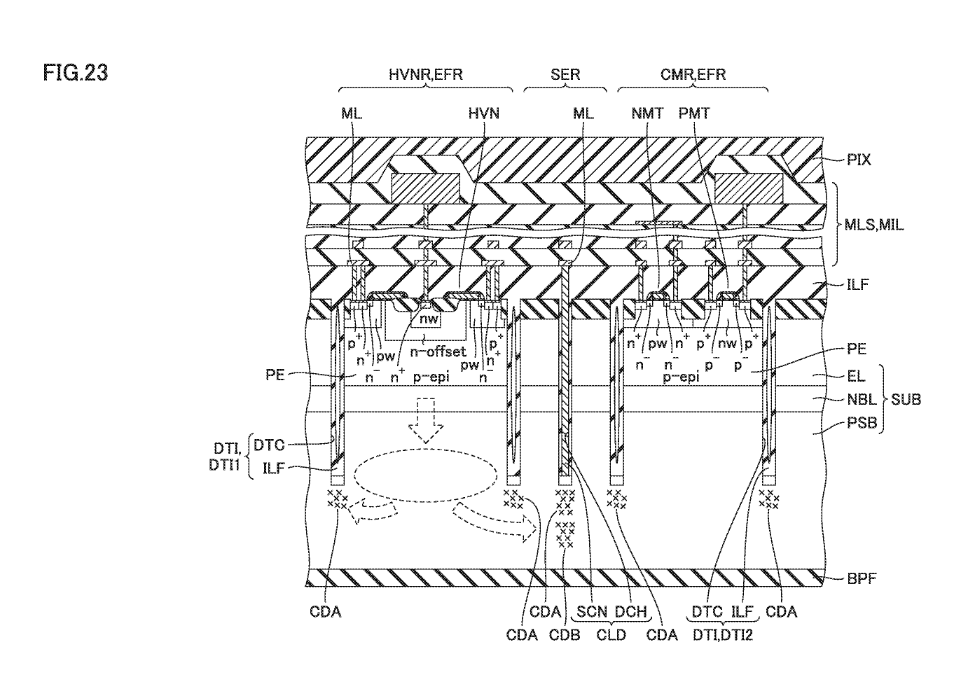

As shown in FIG. 23, this configuration increases the probability that carriers diffusing toward CMOS transistor formation region CMR through p-type substrate PSB are recombined and annihilated in crystal defect region CDA and crystal defect region CDB. Thus, the carriers diffusing toward CMOS transistor formation region CMR are significantly reduced, thereby reliably suppressing malfunction of NMOS transistor NMT or PMOS transistor PMT.

### Fourth Embodiment

Here, variations of a planar structure (pattern) of the substrate contact portion will be described.

In the semiconductor device according to the foregoing embodiments, substrate contact portion CLD is formed in a region of semiconductor substrate SUB that is positioned between high voltage NMOS transistor formation region HVNR and CMOS transistor formation region CMR, by way of example. The arrangement pattern of substrate contact portion CLD is not limited to this example. Its variations will be described.

### FIRST EXAMPLE

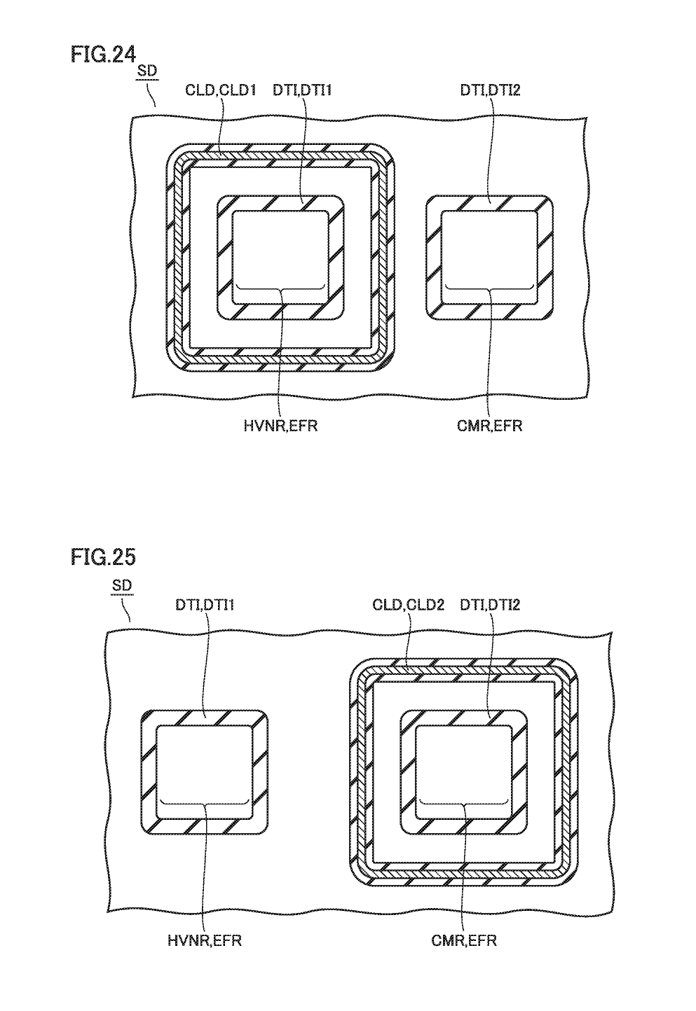

In a first example, as shown in FIG. 24, substrate contact portion CLD is disposed so as to surround the periphery of element isolation insulating film DTI1 defining high voltage NMOS transistor formation region HVNR. Crystal defect region CDA (see FIG. 3, FIG. 20) is formed at a portion of p-type substrate PSB that is positioned immediately below each of substrate contact portion CLD and element isolation insulating film DTI. Here, it is assumed that high voltage NMOS transistor is a semiconductor element in which carriers are likely to be emitted.

In this case, the carriers diffusing in every direction from high voltage NMOS transistor formation region HVNR can be annihilated in crystal defect region CDA. Thus, the carriers diffusing toward the adjacent CMOS transistor formation region CMR or another element formation region (not shown) are reduced, thereby reliably suppressing malfunction of the semiconductor element.

### SECOND EXAMPLE

In a second example, as shown in FIG. 25, substrate contact portion CLD is disposed so as to surround the periphery of element isolation insulating film DTI2 defining CMOS transistor formation region CMR. Crystal defect region CDA (see FIG. 3, FIG. 20) is formed at a portion of p-type substrate PSB that is positioned immediately below each of substrate contact portion CLD and element isolation insulating film DTI. Here, it is assumed that the CMOS transistor is a semiconductor element likely to receive carriers, that is, a semiconductor element into which carriers are likely to flow.

In this case, the carriers diffusing toward CMOS transistor formation region CMR from every direction can be annihilated in crystal defect region CDA. This can reliably suppress malfunction of the semiconductor element, such as a CMOS transistor, into which carriers are likely to flow.

### THIRD EXAMPLE

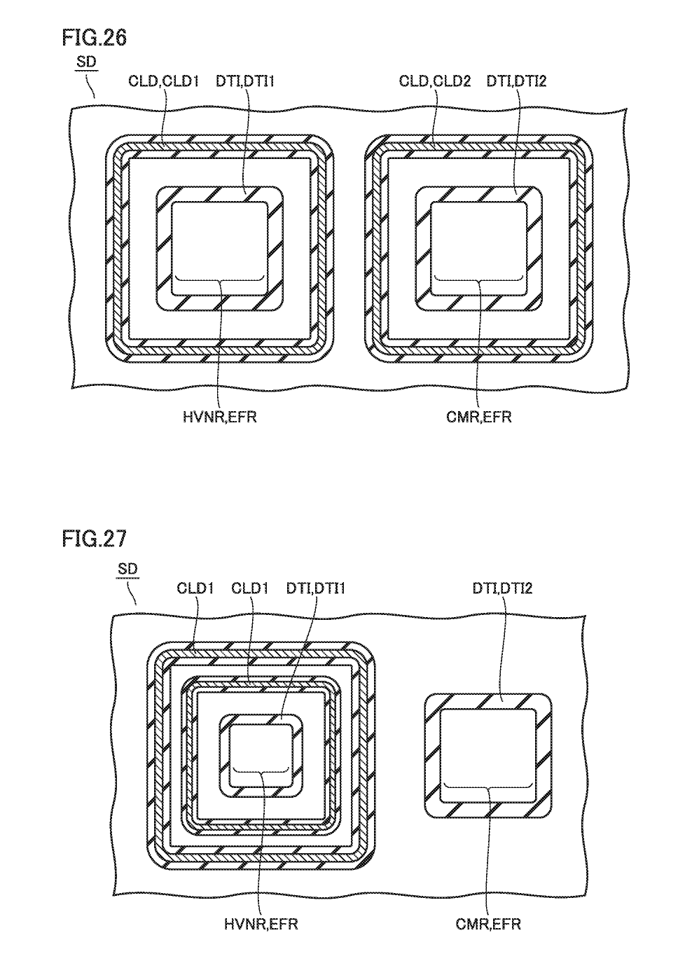

A third example has a combined structure of the first example and the second example. As shown in FIG. 26, substrate contact portion CLD is disposed so as to surround the periphery of element isolation insulating film DTI1 defining high voltage NMOS transistor formation region HVNR. Substrate contact portion CLD is disposed so as to surround the periphery of element isolation insulating film DTI2 defining CMOS transistor formation region CMR. Crystal defect region CDA (see FIG. 3, FIG. 20) is formed at a portion of p-type substrate PSB that is positioned immediately below each of substrate contact portion CLD and element isolation insulating film DTI.

In this case, the carriers diffusing in every direction from high voltage NMOS transistor formation region HVNR can be annihilated in crystal defect region CDA. The carriers diffusing toward CMOS transistor formation region CMR from every direction can also be annihilated in crystal defect region CDA. This can more reliably suppress malfunction of the semiconductor element, such as a CMOS transistor, into Which carriers are likely to flow.

### FOURTH EXAMPLE

In a fourth example, as shown in FIG. 27, substrate contact portion CLD is disposed double so as to surround the periphery of element isolation insulating film DTI1 defining high voltage NMOS transistor formation region HVNR. Crystal defect region CDA (see FIG. 3, FIG. 20) is formed at a portion of p-type substrate PSB that is positioned immediately below each of substrate contact portion CLD and element isolation insulating film DTI. Here, it is assumed that the high voltage NMOS transistor is a semiconductor element in which carriers are likely to be emitted.

In this case, the carriers diffusing in every direction from high voltage NMOS transistor formation region HVNR can be reliably annihilated in crystal defect region CDA. This configuration can more reliably suppress malfunction of the semiconductor element, such as a CMOS transistor, into which carriers are likely to flow.

### FIFTH EXAMPLE

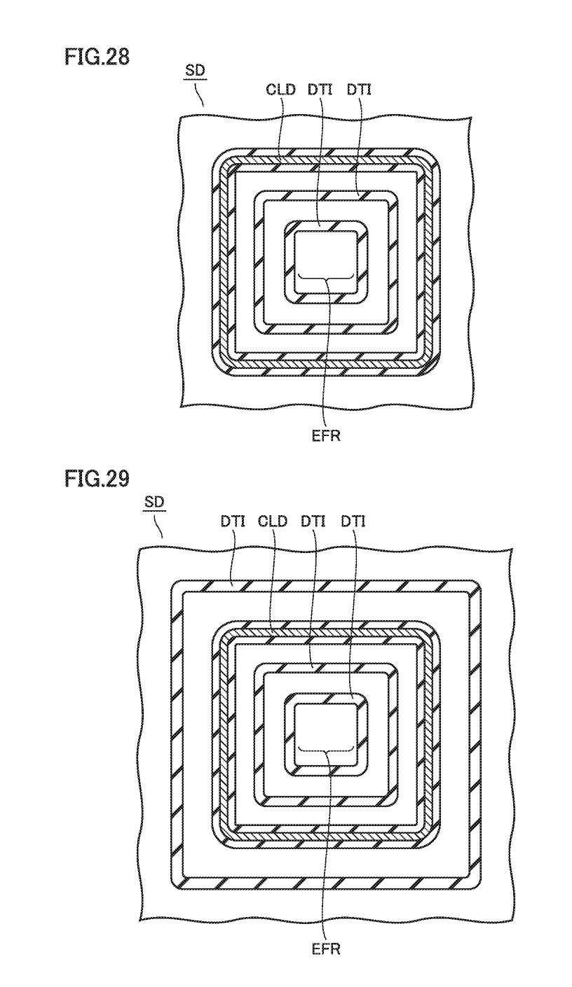

In a fifth example, as shown in FIG. 28, element isolation insulating film DTI is further formed so as to surround the periphery of element isolation insulating film DTI1 defining element formation region EFR. Crystal defect region CDA (see FIG. 3, FIG. 20) is formed at a portion of p-type substrate PSB that is positioned immediately below each of substrate contact portion CLD and element isolation insulating film DTI.

With this configuration, the carriers produced in the semiconductor element formed in element formation region EFR and diffusing in every direction can be annihilated in crystal defect region CDA. Conversely, the carriers diffusing from every direction toward the semiconductor element formed in element formation region EFR can be annihilated in crystal defect region CDA. As a result, malfunction of the semiconductor element can be suppressed reliably.

### SIXTH EXAMPLE

In a sixth example, as shown in FIG. 29, element isolation insulating film DTI is further formed so as to surround substrate contact portion CLD. Crystal defect region CDA (see FIG. 3, FIG. 20) is formed at a portion of p-type substrate PSB that is positioned immediately below each of substrate contact portion CLD and element isolation insulating film DTI.

With this configuration, the carriers produced in the semiconductor element formed in the element formation region and diffusing in every direction can be annihilated reliably in crystal defect region CDA and the like. Conversely, the carriers diffusing from every direction can be annihilated reliably in crystal defect region CDA and the like. As a result, malfunction of the semiconductor element can be suppressed more reliably.

In the foregoing semiconductor device, for convenience of explanation, high voltage NMOS transistor HVNR has been taken as an example of the semiconductor element in which carriers are likely to be emitted, and CMOS transistor CMR has been taken as an example of the semiconductor element into which carriers are likely to flow. They have been illustrated by way of example, and the structure of substrate contact portion CLD or the structure of element isolation insulating film DTI described above is applicable to a semiconductor device including a semiconductor element in which carriers are likely to be emitted and a semiconductor element into which carriers are likely to flow.

Although in the example described above, crystal defect region CDA (see FIG. 3, FIG. 20) is formed at a portion of p-type substrate PSB that is positioned immediately below each of substrate contact portion CLD and element isolation insulating film DTI, crystal defect region CDA is formed at least at a portion of p-type substrate PSB that is positioned immediately below substrate contact portion CLD.

A variety of the structures described in the embodiments can be combined as necessary.

Although the present invention made by the inventors of the invention has been described in detail based on embodiments, it is clearly understood that the present invention is not limited to the foregoing embodiments and susceptible to various modifications without departing from the scope of the invention.

What is claimed is:

1. A semiconductor device comprising:
a semiconductor substrate having a main surface;
a first element formation region defined by a first insulating isolation portion reaching from said main surface to a first depth;
a first semiconductor element formed in said first element formation region;
a second element formation region disposed at a distance from said first element formation region and defined by a second insulating isolation portion reaching from said main surface to said first depth;
a second semiconductor element formed in said second element formation region;
a substrate contact portion formed in a region of said semiconductor substrate that is positioned between said first element formation region and said second element formation region, said substrate contact portion including a portion reaching from said main surface to a second depth; and
a crystal defect region including a first crystal defect region formed at a portion of said semiconductor substrate that is positioned immediately below said substrate contact portion.

2. The semiconductor device according to claim 1, wherein
said crystal defect region includes
a second crystal defect region formed at a portion of said semiconductor substrate that is positioned immediately below said first insulating isolation portion and
a third crystal defect region formed at a portion of said semiconductor substrate that is positioned immediately below said second insulating isolation portion.

3. The semiconductor device according to claim 2, wherein
said first crystal defect region includes
a first crystal defect region first portion and
a first crystal defect region second portion formed at a position deeper than said first crystal defect region first portion.

4. The semiconductor device according to claim 1, wherein
said substrate contact portion is disposed so as to surround at least periphery of said first element formation region, and
said first crystal defect region is formed along said substrate contact portion, at a portion of said semiconductor substrate that is positioned immediately below said substrate contact portion.

5. The semiconductor device according to claim 4, wherein
a plurality of said substrate contact portions are disposed as said substrate contact portion,
a plurality of said substrate contact portions including
a substrate contact first portion and
a substrate contact second portion disposed so as to surround periphery of said substrate contact first portion.

6. The semiconductor device according to claim 4, wherein
a plurality of said first insulating isolation portions are disposed as said first insulating isolation portion,
a plurality of said first insulating isolation portions including
a first insulating isolation first portion defining said first element formation region and
a first insulating isolation second portion disposed inside said substrate contact portion so as to surround periphery of said first insulating isolation first portion.

7. The semiconductor device according to claim 4, wherein
a plurality of said first insulating isolation portions are disposed as said first insulating isolation portion,
a plurality of said first insulating isolation portions including
a first insulating isolation first portion defining said first element formation region and
a first insulating isolation second portion disposed so as to surround said first insulating isolation first portion and said substrate contact portion.

8. A method of manufacturing a semiconductor device, comprising the steps of:
forming a first isolation groove defining a ⁻first element formation region and a second isolation groove defining a second element formation region to reach from a main surface of a semiconductor substrate to a first depth, and forming an opening reaching from said main surface of said semiconductor substrate positioned between said first isolation groove and said second isolation groove to said first depth;
forming a first semiconductor element in said first element formation region;
forming a second semiconductor element in said second element formation region;
forming an insulating film so as to fill said first isolation groove, said second isolation groove, and said opening to form a first insulating isolation portion in said first isolation groove and form a second insulating isolation portion in said second isolation groove;
successively performing processing on a portion of said insulating film buried in said opening and on said semiconductor substrate to form a contact opening passing through said insulating film to reach said first depth;
forming a conductor in said contact opening to form a substrate contact portion; and
injecting an injection seed not concerned with a conductivity type to form a crystal defect region in said semiconductor substrate,
the step of forming said crystal defect region including the step of forming a first crystal defect region at a portion of said semiconductor substrate that is positioned immediately below said substrate contact portion.

9. The method of manufacturing a semiconductor device according to claim 8, wherein
the step of forming said crystal defect region includes the step of injecting a first impurity as said injection seed from said first isolation groove, said second isolation groove, and said opening to form a second crystal defect region at a portion of said semiconductor substrate that is positioned immediately below said first isolation groove, form a third crystal defect region at a portion of said semiconductor substrate that is positioned immediately below said second isolation groove, and form said first crystal defect region at a portion of said semiconductor substrate that is positioned at a bottom of said opening.

10. The method of manufacturing a semiconductor device according to claim 9, wherein
the step of forming said crystal defect region includes the step of injecting a second impurity as said injection seed from said contact opening to form a fourth crystal defect region at a position deeper than said first crystal defect region immediately below a bottom of said contact opening.

11. The method of manufacturing a semiconductor device according to claim 8, wherein
the step of forming said crystal defect region includes the step of injecting a third impurity as said injection seed from said contact opening to form said first crystal defect region at a portion of said semiconductor substrate that is positioned immediately below a bottom of said contact opening.

12. The method of manufacturing a semiconductor device according to claim 8, wherein
said injection seed includes at least any one of carbon, silicon, germanium, and argon.
